(19) United States
(12) Patent Application Publication
(10) Pub. No.: US 2014/0284797 A1
(43) Pub. Date: Sep. 25, 2014

(54) POWER SEMICONDUCTOR DEVICE FABRICATION METHOD, POWER SEMICONDUCTOR DEVICE

(71) Applicant: KABUSHIKI KAISHA TOSHIBA, Tokyo (JP)

(72) Inventors: Yuuji HISAZATO, Tokyo (JP); Hiroki SEKIYA, Kanagawa (JP); Yo SASAKI, Saitama (JP); Kazuya KODANI, Kanagawa (JP); Nobumitsu TADA, Tokyo (JP); Hitoshi MATSUMURA, Kanagawa (JP); Tomohiro IGUCHI, Kanagawa (JP)

(73) Assignee: KABUSHIKI KAISHA TOSHIBA, Tokyo (JP)

(21) Appl. No.: 14/017,209

(22) Filed: Sep. 3, 2013

(30) Foreign Application Priority Data
Mar. 22, 2013 (JP) 2013-059349

(51) Int. Cl. H01L 21/768; H01L 23/00; H01L 23/498

(52) U.S. Cl. CPC H01L 21/76838; H01L 23/49866; H01L 24/85
USPC 257/741; 438/660; 438/121

(57) ABSTRACT

A method for fabricating a power semiconductor device that comprises a base substrate with a conductive layer on a surface of the base substrate and semiconductor components mounted on the base substrate includes forming a hardened layer on the surface of the conductive layer before mounting a semiconductor component on the base substrate. The forming of the hardened layer may optionally be performed using a peening process, for example, a shot peening process, a laser peening process, or an ultrasonic peening process. The conductive layer may comprise a metal such as, for example, aluminum or copper.

### CROSS-REFERENCE TO RELATED APPLICATION

This application is based upon and claims the benefit of priority from Japanese Patent Application No. 2013-059349, filed Mar. 22, 2013, the entire contents of which are incorporated herein by reference.

### FIELD

The embodiments described herein relate generally to a power supply semiconductor device fabrication method and a power semiconductor device.

### BACKGROUND

Semiconductor devices have a cold and hot cycle, in which the temperature rises when the power is on and the temperature drops when the power is off. The semiconductor device expands and shrinks repeatedly due to the cold and hot cycle. However, since the semiconductor device includes materials having different thermal expansion rates, deterioration is caused by the cold and hot cycle, and in particular, the deterioration in junction parts becomes a problem. The deterioration becomes especially serious due to the sharp temperature difference of the cold and hot cycle in power semiconductor device wherein a lot of current flows.

### DESCRIPTION OF THE DRAWINGS

FIG. 1 is a cross-sectional view of the power semiconductor device according to an embodiment.

FIG. 2 is an enlarged cross-sectional view of a conductive layer.

FIGS. 3A and 3B are schematic diagrams illustrating the deformation occurred in the pad due to the cold and hot cycle.

FIGS. 4A to 4C are photographs showing cross-sections of a first embodiment.

FIGS. 5A to 5C are photographs showing cross-sections of a comparative example.

FIG. 6 is a diagram illustrating the measurement result of a second embodiment.

### DETAILED DESCRIPTION

In general, according to one embodiment, a method for fabricating a power semiconductor device that includes a base substrate with a conductive layer on a surface of the base substrate and semiconductor components mounted on the base substrate includes a step of forming a hardened layer on the surface of the conductive layer before mounting a semiconductor component on the base substrate.

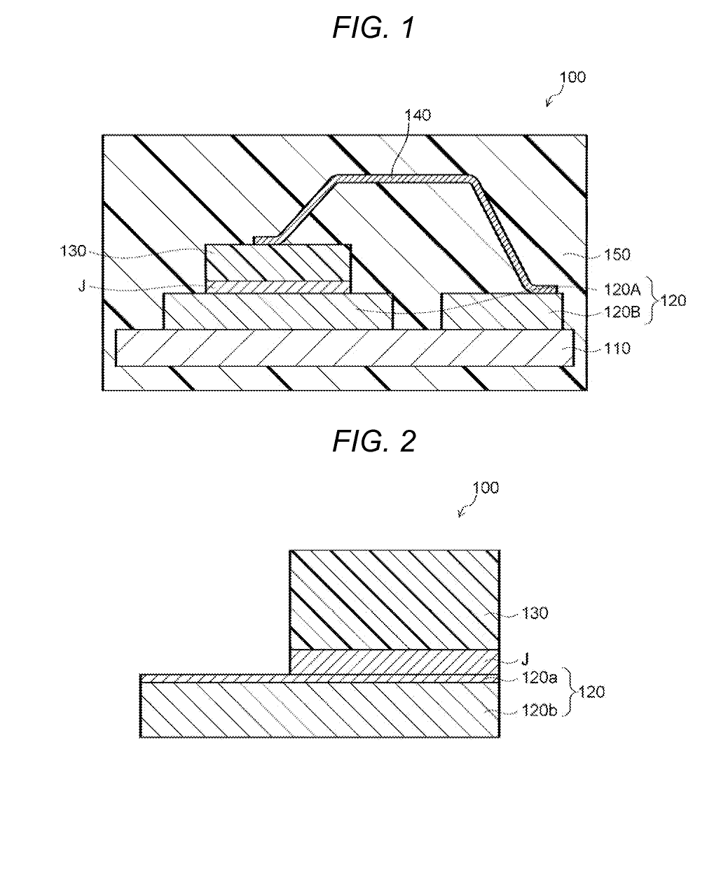

In the following, an example embodiment will be described with reference to the drawings. FIG. 1 is a cross-sectional view of a power semiconductor device 100 according to a first embodiment. The power semiconductor device 100 includes a base substrate 110 for heat dissipation having a conductive layer 120 formed on the surface, a semiconductor element 130 mounted on the base substrate 110, a wire 140 used for connecting a terminal of the semiconductor element 130 and a conductive layer 120, a junction part J where the semiconductor element 130 is bonded to the conductive layer 120, and a sealing resin 150.

The base substrate 110 is made of an insulating material with high thermal conductivity (such as, for example, alumina) used for dissipating the heat generated by the semiconductor element 130. The conductive layer 120 formed on the surface of the base substrate 110 is made of a material with high electroconductivity (such as, for example, aluminum (Al) or copper (Cu)). The conductive layer 120 forms at least pads 120A, 120B and wirings (not shown in the drawing) connected to pads 120A, 120B. The wirings are connected to the external electrodes of the power semiconductor device 100 used for making connection to the outside.

FIG. 2 is an enlarged cross-sectional view of the conductive layer 120, which comprises a hardened layer (120a) and a base material layer (120b). A hardened layer 120a having a hardness greater than the base material layer 120b is formed on the surface of the conductive layer 120. The hardened layer 120a is formed by carrying out, for example, shot peening, laser peening, or ultrasonic peening to cause plastic deformation on the surface of the conductive layer 120. In this example, the thickness of the hardened layer 120a is preferred to be 1 μm or thicker because if the thickness of the hardened layer 120a is smaller than 1 μm, the effect for restraining deformation of the conductive layer 120 caused by the cold and hot cycle becomes less significant.

When the hardened layer 120a is formed by means of shot peening, it is preferred, but not required, that the blasting material have a generally spherical shape so that it will not be buried in the conductive layer 120. Also, the size of the blasting material (e.g., sphere diameter) is preferred, but not required, to be in the range of 2-100 μm. If the size of the blasting material is too small, the blasting material may be buried in the conductive layer 120. For example, if the thickness of the hardened layer 120a is 1 μm or thicker, when the size of the blasting material is smaller than 1 μm, it is highly possible that the blasting material will be buried in the hardened layer 120a.

When the size of the blasting material exceeds 100 μm, the surface roughness (Rz) of the hardened layer 120a may increase. In fact, when a blasting material with a size of 1000 μm and a blasting material with a size of 100 μm are used to carry out shot peening, the surface roughness (Rz) of the hardened layer 120a formed when using the blasting material with a size of 100 μm is about half (½) of that when using the blasting material with a size of 1000 μm. The blasting material is shot by the force of, for example, 0.3 MPa, 0.6 MPa, 0.8 MPa. Therefore, for the blasting material with a fine size, the surface state of the hardened layer 120a is good, and the surface roughness (Rz) of the hardened layer 120a can be controlled effectively.

Here, the blasting material need not be completely uniform in size or perfectly spherical in shape. The size of the blasting material may comprise a range of dimensions, for example, within 2 μm to 100 μm diameters for generally spherical materials. The shape of the blasting material is preferably spherical, but other shapes maybe used.

When shot peening is performed to the object (base material) at a temperature higher than the room temperature, the blasting force of the blasting material can be lower.

However, when aluminum (Al) is used as the material forming the conductive layer 120, it is not typically desirable to carry out shot peening at high temperature. Therefore, it is preferred to carry out shot peening at a temperature of, for example, 100° C. or lower. If the temperature is 100° C. or lower, the blasting material can be restrained from being buried in the base material (e.g., aluminum (Al)).

When copper (Cu) is used as the material forming the conductive layer 120, there is less worry that the blasting material burying in the base material (copper (Cu)) . However, oxidation becomes significant when the temperature exceeds 100° C. Therefore, when shot peening is carried out at a temperature higher than 100° C., it is preferable to carry out shot peening in a non-oxidizing atmosphere in order to restrain oxidation of the copper (Cu). However, since it is difficult to carry out shot peening under a reduced pressure, it is effective to carry out shot peening in a nitrogen (N₂) atmosphere or the like.

It is also possible to form a nickel (Ni) plating layer on the surface of the conductive layer 120. In this case, it is preferred to form the nickel (Ni) plating layer after the hardened layer 120a is formed on the surface of the conductive layer 120. The reason for this sequencing will be described later.

The semiconductor element 130 is a power semiconductor element, such as diode or Insulated Gate Bipolar Transistor (IGBT). The diode or IGBT is diced into the desired size after being formed on a substrate made of silicon (Si), silicon carbide (SiC), gallium nitride (GaN), or the like. The semiconductor element 130 is bonded (mounted) on the pad 120A of the conductive layer 120 by means of dry/wet plating using tin (Sn)-based solder, sintered silver (Ag) particle paste, tin (Sn), copper (Cu), nickel (Ni), or the like, solid-phase/liquid-phase diffusion bonding using a sheet material or the like, ultrasonic bonding, or the like.

The wire 140 is a bonding wire that connects the connection pad (not shown in the drawing) of the semiconductor element 130 and the pad 120B of the conductive layer 120. Gold (Au) with high electroconductivity is often used as the material of the wire 140, but inexpensive copper (Cu) has also been used in recent years.

The sealing resin 150 may be a thermosetting molding material that is mainly composed of an epoxy resin and contains silica filler and the like. The sealing resin 150 is used to seal the semiconductor element 130 to protect the semiconductor element 130 from the deterioration caused by light, heat, humidity, or the like in the environment.

For the semiconductor element 130 as a power semiconductor element, the temperature rises during the operation (when the power is on) and the temperature drops when the element is idle (the power is off). Therefore, the so-called cold and hot cycle occurs. When the junction part J between the semiconductor element 130 and the pad 120A of the conductive layer 120 is subjected to the cold and hot cycle, the power cycle or the like due to power on/off over long time, cracks will occur in junction part J. When the cold and hot cycle or the power cycle is further repeated, the cracks in junction part J will grow to cause fracture that leads to failures or unstable performance of the power semiconductor device 100.

As a reason that causes the cracks, for example, strain occurs in the solder of junction part J as a result of the cold and hot cycle. The solder is recrystallized, and the cracks grow/develop. When the crystal grain boundary is aligned linearly, the cracks will develop quickly, and the time before the power semiconductor device 100 fails will be shortened. In other words, the power semiconductor device 100 has a short service life.

As another reason, when the sealing resin 150 peels off from the base substrate 110 for heat dissipation, the restraint of the entire body is lost. As a result, cracks occur/grow in the junction of the solder or the like, and the time before failures is shortened. These reasons vary depending on the material forming the power semiconductor device 100.

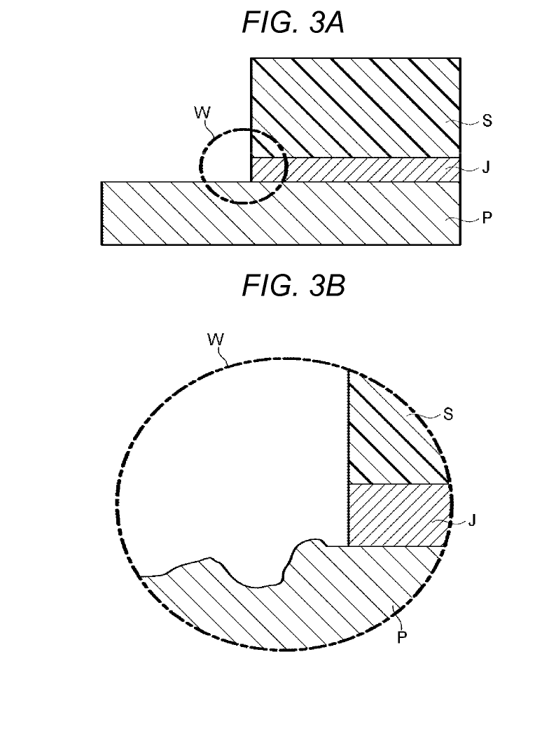

FIGS. 3A and 3B are schematic diagrams illustrating the deformation that occurred in a pad P due to the cold and hot cycle. FIG. 3A is a cross-sectional view of semiconductor element S mounted via junction part J on pad P. FIG. 3B is an enlarged view of frame W of FIG. 3A. Unlike the power semiconductor device 100 according to the embodiment, no hardened layer is formed on the surface of pad P shown in FIG. 3A and FIG. 3B.

As shown in FIG. 3B, cracks occur in junction part J due to the cold and hot cycle during the operation of semiconductor element S. Also, the cracks in junction part J may grow significantly as the deformation of pad P becomes significant. Also, when Ag or Cu is contained in a Sn-based solder material, as thermal stress is repeated, a large intermetallic compound is segregated in the crystal grain boundary section of the recrystallized Sn. As a result, the crystal grain boundary section becomes fragile. Cracks may occur/grow to shorten the service life.

As described above, cracks may occur in junction part J or pad P (conductor layer) may deform due to the cold and hot cycle in the power semiconductor device. The cracks in junction part J may develop significantly due to the deformation of pad P. In this case, the service life of the semiconductor device may be shortened.

For the power semiconductor device 100, however, since the hardened layer 120a is formed on the surface of the conductive layer 120 to restrain deformation of the conductive layer 120 caused by the cold and hot cycle, occurrence of the cracks in junction part J can be restrained. Even if cracks occur, the cracks in junction part J can be prevented from developing significantly. As a result, the service life of the power semiconductor device 100 can be prolonged.

### First Embodiment

In the following, a first embodiment will be described as an example. In this embodiment, after a nickel (Ni) plating layer was formed on an aluminum (Al) substrate, samples A1-A3 (first embodiment) and samples B1-B3 (comparative example) sealed with a resin were prepared. Shot peening was performed to form a hardened layer on the surface of aluminum (Al) substrate for samples A1-A3.

Then, a thermal impact machine was used to apply cold and hot cycle to each of samples A1-A3 and B1-B3. In one cold and hot cycle, the temperature is changed from −40° C. to 125° C. and then from 125° C. to −40° C. The cold and hot cycle was performed 0 (zero) time to samples A1 and B1, 200 times to samples A2 and B2, and 400 times to samples A3 and B3. In each cycle, each of the changes from −40° C. to 125° C. and from 125° C. to −40° C. lasted 15 min.

### Samples A1-A3

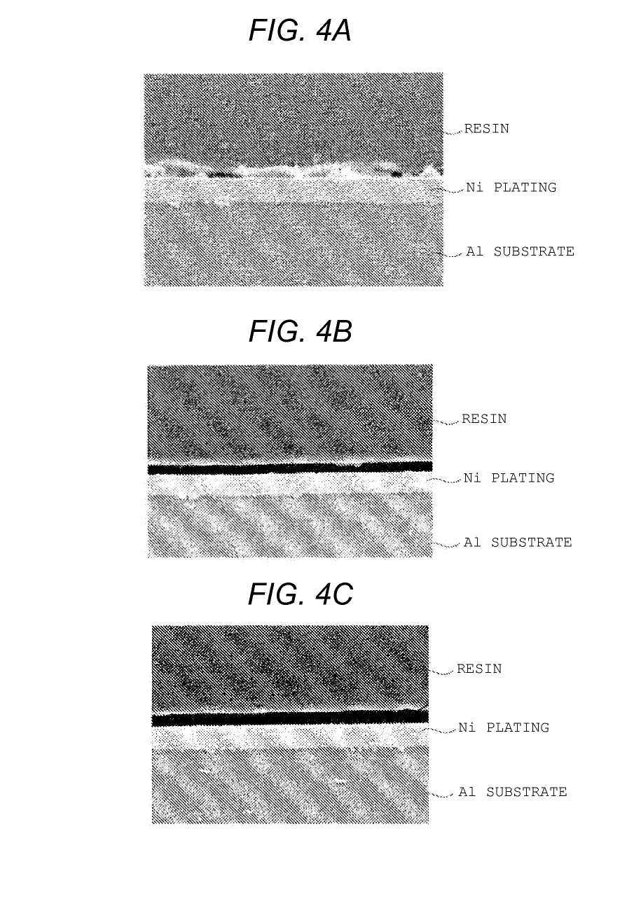

FIGS. 4A to 4C are photographs showing cross-sections (SEM picture) of samples A1-A3 obtained using scanning electron microscopy. FIG. 4A shows a cross-sectional picture of sample Al (0 cycle) . FIG. 4B shows a cross-sectional picture of sample A2 (200 cycles) . FIG. 4C shows a cross-sectional picture of sample A3 (400 cycles) . As shown in FIG. 4, for samples A1-A3 having a hardened layer formed on the surface of the aluminum (Al) substrate, the deformation caused by the cold and hot cycle was restrained.

### Samples B1-B3

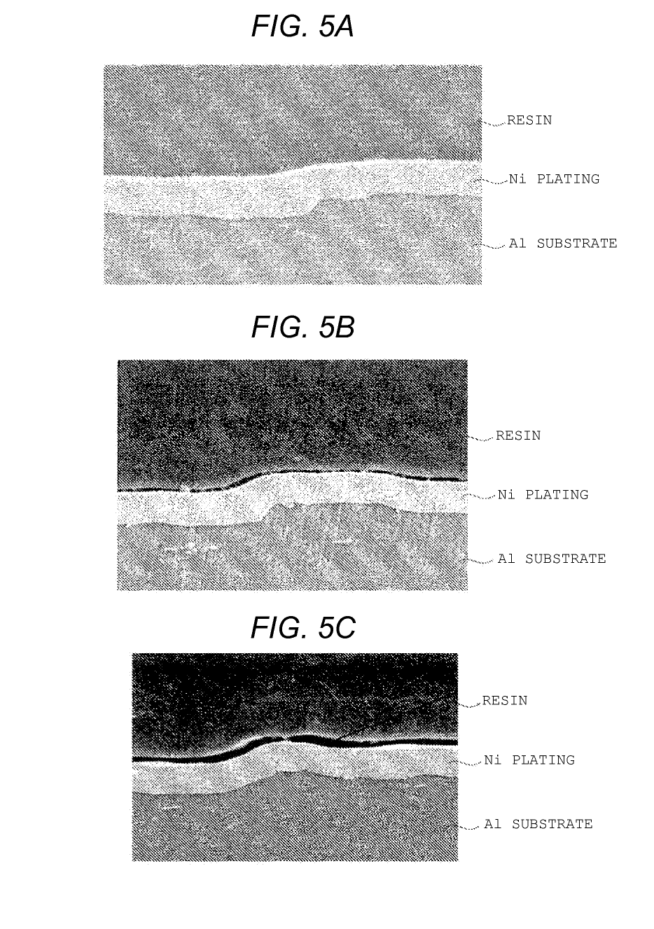

FIGS. 5A to 5C are photographs showing cross-sections (SEM picture) of samples B1-B3 obtain using scanning electron microscopy. FIG. 5A is a photograph showing a cross-section of sample B1 (0 cycle). FIG. 5B is a photograph showing a cross-section of sample B2 (200 cycles). FIG. 5C is a photograph showing a cross-section of sample B3 (400 cycles). As shown in FIGS. 5A to 5C, for samples B1-B3 that had no hardened layer formed on the surface of the aluminum (Al) substrate, the deformation caused by the cold and hot cycle was not restrained and the pad deformed.

As described above, when a hardened layer was formed on the surface of the pad, the deformation caused by the cold and hot cycle could be restrained.

### Second Embodiment

In the following, a second embodiment will be described as an example. In the second embodiment, after shot peening was performed to form a hardened layer on the surface of the aluminum (Al) substrate, a Ni plating layer was formed to obtain sample C. For sample D, shot peening was performed to form a hardened layer after a Ni plating layer was formed on the surface of an aluminum (Al) substrate. Vickers hardness (HV) was measured at multiple depths for samples C and D.

To measure the Vickers hardness (HV), a pyramid-shaped indenter formed using a regular quadrangular pyramid diamond with face-to-face angle α=136° C. was pressed into the surface of samples C and D. The surface area S/mm² was calculated from the diagonal length d/mm of the dent left after the load was removed. Then, the Vickers hardness was calculated by dividing the test load F/kgf by surface area S/mm².

Table 1 shows the measurement results.

TABLE 1

Vickers hardness (HV)

| Distance from | Sample | Sample |
|---|---|---|
| the surface | C | D |
| 0.01 | 300 | 300 |
| 0.02 | 110 | 55 |
| 0.04 | 95 | 55 |
| 0.08 | 51 | 51 |
| 0.10 | 53 | 51 |
| 0.30 | 54 | 53 |
| 0.50 | 51 | 51 |
| 1.00 | 50 | 51 |

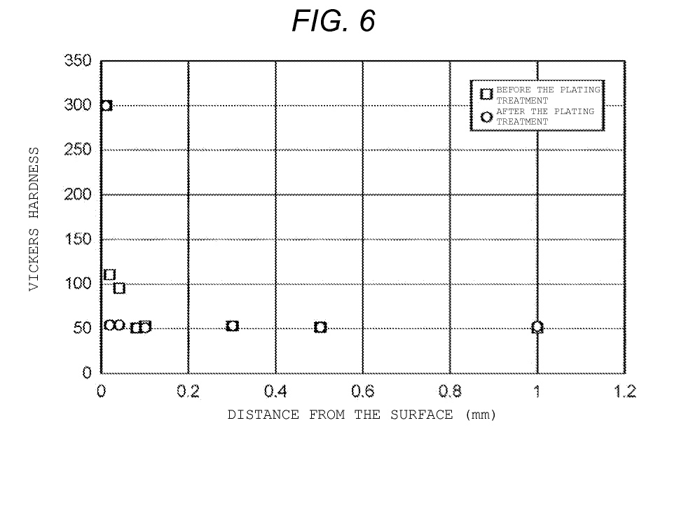

FIG. 6 shows the measurement results of Table 1 in a diagram. In FIG. 6, the ordinate represents the Vickers hardness (HV), while the abscissa represents the distance from the surface (mm). Also, in FIG. 6, the measurement result of sample Cis shown by a square (□), while the measurement result of sample D is shown by a circle (◯).

As can be seen from Table 1 and FIG. 6, the hardness of the nickel (Ni) plating of sample D (the surface was hardened after the nickel (Ni) plating was formed) was almost the same as sample C (the surface was hardened before the nickel (Ni) plating was formed). However, for sample D, the Vickers hardness decreased significantly in the depth direction from the surface. The Vickers hardness became almost the same as that (about 50) of the base material (aluminum (Al)).

On the other hand, for sample C, the Vickers hardness decreased gradually in the depth direction from the surface. The Vickers hardness decreases to the same level as that of the base material (aluminum (Al)) at the depth of about 0.1 mm. In other words, when peening or other hardening treatment is carried out after nickel (Ni) plating or other surface treatment, there is almost no change in the hardness on the surface, and the hardness becomes the same as that inside the sample. Therefore, when the cold and hot cycle is repeated, it is highly possible that the Al substrate will deform to adversely affect the junction part. Consequently, in the case of performing plating or other surface treatment, it is preferred to carry out the surface treatment after the peening or other hardening treatment.

### Other Embodiments

While certain embodiments have been described, these embodiments have been presented by way of example only, and are not intended to limit the scope of the disclosure. Indeed, the embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A method for fabricating a power semiconductor device that includes a base substrate with a conductive layer on a surface of the base substrate and semiconductor components mounted on the base substrate, the method comprising:
forming a hardened layer on the surface of the conductive layer before mounting a semiconductor component on the base substrate.

2. The method of claim 1, wherein a shot peening process is used in forming the hardened layer on the surface of the conductive layer.

3. The method of claim 2, wherein a blasting material used in the shot peening process comprises a material with a generally spherical shape having diameter that is between two microns and one hundred microns.

4. The method of claim 1, wherein the conductive layer is aluminum or copper.

5. The method of claim 4, wherein the conductive layer is copper and the step of forming the hardened layer on the surface of the conductive layer is performed at a temperature above 100° C. in a nitrogen environment.

6. The method of claim 4, wherein the conductive layer is aluminum and the step of forming the hardened layer on the surface of the conductive layer is performed at a temperature below 100° C.

7. The method of claim 1, further comprising plating a metal layer on the surface of the conductive layer after forming the hardened layer on the surface of the conductive layer.

8. The method of claim 7, wherein the metal layer is nickel.

9. The method of claim 1, wherein a thickness of the hardened layer is greater than one micron.

10. The method of claim 1, wherein laser peening or ultrasonic peening is used in forming the hardened layer on the surface of the conductive layer.

11. A method for fabricating a power semiconductor device, comprising:
obtaining a base substrate;
forming a conductive layer on a surface of the base substrate;
forming a hardened layer on a surface of the conductive layer using a peening process; and
mounting a semiconductor component to the conductive layer.

12. The method of claim 11, further comprising:
plating a metal layer on the hardened layer before mounting the semiconductor component to the conductive layer.

13. The method of claim 11, wherein the peening process is a shot peening process, a laser peening process, or an ultrasonic peening process.

14. The method of claim 11, wherein the base substrate is alumina.

15. A semiconductor device, comprising:
a base substrate with a conductive layer on a surface of the base substrate; and
a semiconductor component mounted on the conductive layer, wherein the conductive layer includes a hardened layer and a base material layer, the hardened layer on a surface of the conductive layer and having a hardness greater than a hardness of the base material layer.

16. The semiconductor device of claim 15, further comprising a plating layer on the surface of the conductive layer.

17. The semiconductor device of claim 16, wherein the plating layer comprises nickel.

18. The semiconductor device of claim 15, wherein the hardened layer has a thickness greater than approximately one micron.

19. The semiconductor device of claim 15, wherein the hardened layer is formed by a shot peening process.

20. The semiconductor device of claim 15, further comprising a semiconductor component mounted on the conductive layer.
